(19) United States
(12) Patent Application Publication
(10) Pub. No.: US 2026/0214605 A1
(43) Pub. Date: Jul. 23, 2026

(54) METHOD AND DEVICE FOR SYNCHRONIZING TIME DELAY CIRCUIT

(71) Applicant: SANECHIPS TECHNOLOGY CO., LTD., Shenzhen, Guangdong (CN)

(72) Inventors: Teng FAN, Shenzhen, Guangdong (CN); Xinxing HUANG, Shenzhen, Guangdong (CN); Guijin ZHOU, Shenzhen, Guangdong (CN); Yanyan ZHAO, Shenzhen, Guangdong (CN)

(21) Appl. No.: 19/142,281

(22) PCT Filed: Sep. 25, 2023
(86) PCT No.: PCT/CN2023/120968

§ 371 Date: Jun. 23, 2025

(30) Foreign Application Priority Data
Dec. 26, 2022 (CN) 202211676593.4

(51) Int. Cl. H04W 56/00; G11C 7/22

(52) U.S. Cl. CPC H04W 56/004; G11C 7/222; H04W 56/001

(57) ABSTRACT

Disclosed are a method and a device for synchronizing the time delay circuit. The method includes: initializing, by a radio frequency chip, all clock dividers based on a synchronization pulse signal generated by an air interface pulse signal, to synchronize initial phases of a plurality of system clocks generated by frequency division of a high-frequency clock; and aligning a read pointer or a write pointer at a first buffer RAM of the radio frequency chip to synchronize a plurality of sending channels based on the synchronization pulse signal.

### CROSS-REFERENCE TO RELATED APPLICATIONS

This application claims priority to Chinese Patent Application No. 202211676593.4, filed with the State Intellectual Property Office of China on Dec. 26, 2022, the entire disclosure of which is incorporated herein by reference.

### TECHNICAL FIELD

The present application relates to the technical field of communications, and in particular to a method and a device for synchronizing a time delay circuit.

### BACKGROUND

In recent years, 5G communication has developed rapidly. Technologies, such as massive multiple input multiple output (MIMO), and global positioning system pulse per second (GPS 1PPS) timing have improved the system capacity and clock accuracy. Accordingly, higher requirements for accuracy of the digital link delay of the baseband and the radio frequency transceiver systems have been put forward. To reduce design complexity and power consumption, digital links will adopt a plurality of clock domains. Factors, such as asynchronous processing of clock domains, differences in reset path lengths, and changes in integrated circuit process characteristics (such as process corners, power supply voltage and temperature, which are collectively referred to as Pressure-Volume-Temperature, PVT) will cause differences in digital link delays during initial power-on process and operation process. These differences will be manifested in the multi-antenna form of the product, and data alignment processing is required.

### SUMMARY

Embodiments of the present application provide a method and a device for synchronizing a time delay circuit, to solve the at least problems of low accuracy for delay calibration in the related art.

An embodiment of the present application provides a method for synchronizing the time delay circuit, which includes: initializing, by a radio frequency chip, all clock dividers based on a synchronization pulse signal generated by an air interface pulse signal, to synchronize initial phases of a plurality of system clocks generated by frequency division of a high-frequency clock; and aligning a read pointer or a write pointer at a first buffer random access memory (RAM) of the radio frequency chip to synchronize a plurality of sending channels based on the synchronization pulse signal.

An embodiment of the present application further provides a method for synchronizing a time delay circuit, including: aligning a read pointer or a write pointer at a second buffer RAM of a main control chip based on a synchronization pulse signal generated by an air interface pulse signal, to synchronize a plurality of receiving channels.

Another embodiment of the present application provides a device for synchronizing a time delay circuit, applied to a radio frequency chip, including: an initialization module, configured to initialize all clock dividers based on a synchronization pulse signal generated by an air interface pulse signal, to synchronize initial phases of a plurality of system clocks generated by frequency division of a high-frequency clock; and an alignment module, configured to align a read pointer or a write pointer at a first buffer RAM of the radio frequency chip based on the synchronization pulse signal, to synchronize a plurality of sending channels.

Another embodiment of the present application provides a device for synchronizing a time delay circuit, applied to a main control chip, including: a synchronization module, configured to align a read pointer or a write pointer at a second buffer RAM of the main control chip based on a synchronization pulse signal generated by an air interface pulse signal, to synchronize a plurality of receiving channels.

Another embodiment of the present application provides a computer-readable storage medium. The computer-readable storage medium stores a computer program, and when the computer program is executed, steps of the method for synchronizing the time delay circuit as mentioned above are implemented.

Another embodiment of the present application provides an electronic device including a memory and a processor. A computer program is stored in the memory. When the computer program is executed by the processor, steps of the method for synchronizing the time delay circuit as mentioned above are implemented.

### BRIEF DESCRIPTION OF THE DRAWINGS

FIG. 1 is a hardware structure block diagram of a computer terminal for operating a method for synchronizing a time delay circuit according to an embodiment of the present application.

FIG. 2 is a flowchart of the method for synchronizing the time delay circuit according to an embodiment of the present application.

FIG. 3 is another flowchart of the method for synchronizing the time delay circuit according to an embodiment of the present application.

FIG. 4 is a structure block diagram of a device for synchronizing the time delay circuit according to an embodiment of the present application.

FIG. 5 is another structure block diagram of the device for synchronizing the time delay circuit according to an embodiment of the present application.

FIG. 6 is a flowchart showing system synchronization calibration according to an embodiment of the present application.

FIG. 7 is a schematic diagram showing clock alignment according to an embodiment of the present application.

FIG. 8 is a schematic diagram of a time delay sending circuit with high precision according to an embodiment of the present application.

FIG. 9 is a schematic diagram of a time delay receiving circuit with high precision according to an embodiment of the present application.

### DETAILED DESCRIPTION OF THE EMBODIMENTS

Embodiments of the present application will be described in detail below with reference to the accompanying drawings and in combination with the embodiments.

It should be noted that the terms “first”, “second”, and the like in the specification and claims of the present application and the above-mentioned drawings are used to distinguish similar objects, and are not necessarily used to describe a specific order or sequence.

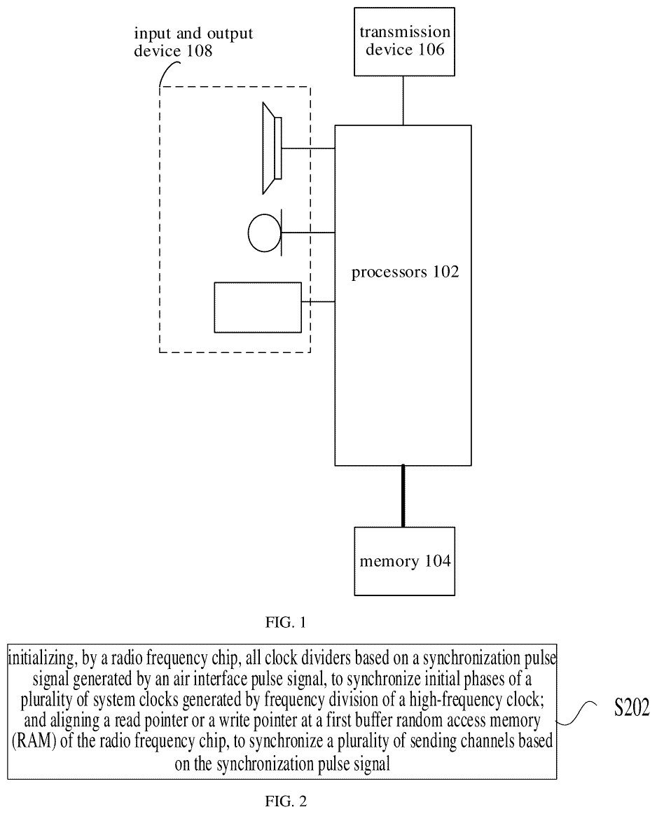

Embodiments of the method provided in the present application can be executed in a mobile terminal, a computer terminal or a similar computing device. Taking the method executed in the computer terminal as an example, FIG. 1 is a hardware structure block diagram of a computer terminal for operating a method for synchronizing a time delay circuit according to an embodiment of the present application. As shown in FIG. 1, the computer terminal may include one or more (only one is shown in FIG. 1) processors 102 (the processor 102 may include but is not limited to a processing device, such as a microprocessor (Central Processing Unit, MCU) or a programmable logic device (Field Programmable Gate Array, FPGA)) and a memory 104 used to store data. The above-mentioned computer terminals may further include a transmission device 106 used for communication, and an input and output device 108. Those skilled in the art can understand that the structure shown in FIG. 1 is only for illustration and does not limit the structure of the above-mentioned computer terminal. For example, the computer terminal may further include more or fewer components than those shown in FIG. 1, or have a configuration different from that shown in FIG. 1.

The memory 104 may be configured to store computer programs, for example, software programs and modules of the application software, such as the computer program corresponding to the method for synchronizing the time delay circuit in the embodiment of the present application. The processor 102 executes various functional applications and performs data processing by operating the computer program stored in the memory 104. That is, the processor 102 implements the above-mentioned method. The memory 104 may include a high-speed random access memory, and may further include a non-volatile memory, such as one or more magnetic storage devices, a flash memory, or other non-volatile solid-state memory. In some embodiments, the memory 104 may further include a remote memory set relative to processor 102, and these remote memories may be connected to the computer terminal via the network. Embodiments mentioned above of the network include, but are not limited to, the Internet, the intranet, the local area network, the mobile communication network, and combinations thereof.

The transmission device 106 is configured to receive or send data via the network. The specific embodiment of the above network may include a wireless network provided by a communication provider for a computer terminal. In an embodiment, the transmission device 106 includes a network adapter (Network Interface Controller, referred to as NIC), which can be connected to other network devices through a base station, so as to communicate with the Internet. In an embodiment, the transmission device 106 can be a radio frequency module, which is configured to communicate with the Internet wirelessly.

At present, for data alignment processing that can be used to overcome the difference in delay of digital links, the adopted method is to construct special excitation data, perform double-point sampling on digital link data, analyze according to the correlation algorithm to obtain the transmission delay of the data link, and then correct the alignment data. The entire algorithm analysis process is relatively complex and cumbersome, and the cost is high. First, it is necessary to construct corresponding excitation data for processing according to the data processing methods in different scenarios of digital links of different systems. Secondly, offline analysis cannot achieve instant application of products, and online analysis will consume a large amount of software and hardware resources and increase power consumption. Finally, whether it is the initialization correction of the power-on process or the re-correction during normal operation, the overall time consumption is relatively long, which is not conducive to quickly completing the high-precision timing of the system.

The present application provides a method for synchronizing the time delay circuit operating on the above-mentioned computer terminal. FIG. 2 is a flowchart of the method for synchronizing the time delay circuit according to an embodiment of the present application. As shown in FIG. 2, the process includes step S202.

Step S202, initializing, by a radio frequency chip, all clock dividers based on a synchronization pulse signal generated by an air interface pulse signal, to synchronize initial phases of a plurality of system clocks generated by frequency division of a high-frequency clock; and aligning a read pointer or a write pointer at a first buffer random access memory (RAM) of the radio frequency chip, to synchronize a plurality of sending channels based on the synchronization pulse signal.

In step S202, the aligning the read pointer or the write pointer at the first buffer RAM of the radio frequency chip based on the synchronization pulse signal includes: resetting the read pointer of the first buffer RAM to a first initial position based on a first synchronization pulse signal; and resetting the write pointer of the first buffer RAM to a second initial position based on a second synchronization pulse signal.

In an embodiment, before the resetting the read pointer of the first buffer RAM to the first initial position based on the first synchronization pulse signal, the method for synchronizing the time delay circuit further includes: setting a depth of the first buffer RAM to enable a displacement of the read pointer in one period of the air interface pulse signal to be a multiple of the depth of the first buffer RAM.

In an embodiment, before the resetting the write pointer of the first buffer RAM to the second initial position based on the second synchronization pulse signal, the method for synchronizing the time delay circuit further includes: generating, by a main control chip, the second synchronization pulse signal based on the air interface pulse signal, and synchronizing a timing of sending the second synchronization pulse signal according to a writing data timing of the write pointer of the first buffer RAM.

In an embodiment, the synchronizing the timing of sending the second synchronization pulse signal includes: attaching the second synchronization pulse signal to a data frame header and sending the second synchronization pulse signal to the first buffer RAM.

In an embodiment, the resetting the write pointer of the first buffer RAM to the second initial position based on the second synchronization pulse signal includes: after the second synchronization pulse signal reaches a write side of the first buffer RAM, comparing, by the radio frequency chip, a current position of a write address pointer of the first buffer RAM with the second initial position; in response to that the current position of the write address pointer of the first buffer RAM is not the second initial position, resetting the write address pointer of the first buffer RAM to the second initial position.

In an embodiment, the method for synchronizing the time delay circuit further includes: setting a first address comparison window; after the second synchronization pulse signal reaches the write side of the first buffer RAM, in response to that the current position of the write address pointer of the first buffer RAM falls within a range where the second initial position overlaps the first address comparison window, skipping resetting the current position of the write address pointer of the first buffer RAM.

Through the above steps, the initial phases of a plurality of system clocks generated by frequency division the high-frequency clock are synchronized based on the air interface pulse signal. At the same time, the read pointer or the write pointer are further aligned at the first buffer RAM of the radio frequency chip, and the clock domain is compensated, so that the delay calibration accuracy can be improved to the nanosecond level. The problem of low delay calibration accuracy in the related art is solved, and the delay calibration accuracy effect is improved.

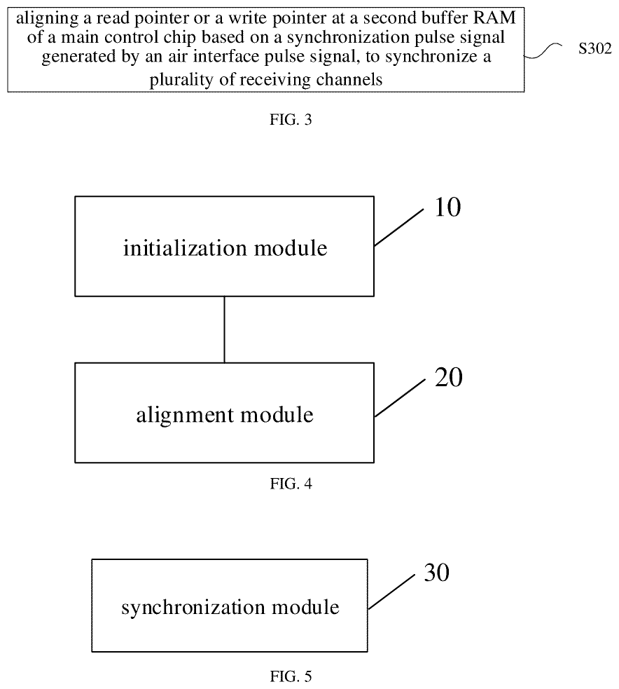

FIG. 3 is another flowchart of the method for synchronizing the time delay circuit according to an embodiment of the present application. As shown in FIG. 3, the process includes step S302.

Step S302, aligning a read pointer or a write pointer at a second buffer RAM of a main control chip based on a synchronization pulse signal generated by an air interface pulse signal, to synchronize a plurality of receiving channels.

In step S302, the aligning the read pointer or the write pointer at the second buffer RAM of the main control chip based on the synchronization pulse signal generated by the air interface pulse signal includes: resetting the read pointer of the second buffer RAM to a third initial position based on a third synchronization pulse signal; and resetting the write pointer of the second buffer RAM to a fourth initial position based on a fourth synchronization pulse signal.

In an embodiment, before the resetting the read pointer of the second buffer RAM to the third initial position based on the third synchronization pulse signal includes: setting a depth of the second buffer RAM, to enable a displacement of the read pointer in one period of the air interface pulse signal is a multiple of the depth of the second buffer RAM.

In an embodiment, the resetting the write pointer of the second buffer RAM to the fourth initial position based on the fourth synchronization pulse signal includes: generating, by a radio frequency chip, the fourth synchronization pulse signal based on the air interface pulse signal, attaching the fourth synchronization pulse signal to a data frame header and sending the fourth synchronization pulse signal to the second buffer RAM.

In an embodiment, the resetting the write pointer of the second buffer RAM to the fourth initial position based on the fourth synchronization pulse signal includes: in response to that the fourth synchronization pulse signal is sent to a write side of the second buffer RAM for a first time, resetting, by the main control chip, the write pointer of the second buffer RAM to the fourth initial position; and in response to that the fourth synchronization pulse signal is sent to the write side of the second buffer RAM not for the first time, comparing, by the main control chip, a current position of a write address pointer of the second buffer RAM with the fourth initial position, and resetting the write address pointer of the second buffer RAM to the fourth initial position in response to that the current position of the write address pointer of the second buffer RAM is not the fourth initial position.

In an embodiment, the resetting the write pointer of the buffer RAM to a second initial position based on a second synchronization pulse signal further includes: setting a second address comparison window, after the fourth synchronization pulse signal reaches the write side of the second buffer RAM, in response to that the current position of the write address pointer of the second buffer RAM falls within a range where the fourth initial position overlaps the second address comparison window, skipping resetting the current position of the write address pointer of the second buffer RAM.

Through the above steps, synchronization of multiple RX channels of a single chip can be achieved, and synchronization of a plurality of RX channels of a multi-chip system can also be achieved.

Through the description of the above implementation, those skilled in the art can clearly understand that the method according to the above embodiments can be implemented by means of software plus the necessary general hardware platform, and of course, it can also be implemented by hardware, but in many cases the former is a better implementation. On this basis, technical solutions of the present application, or the part that contributes to the related art, can be embodied in the form of a software product, and the computer software product is stored in a storage medium (such as a read-only memory/random access memory (ROM/RAM), a disk, or an optical disk), and includes several instructions for enabling a terminal device (which can be a mobile phone, a computer, a server, or a network device, and the like) to execute the methods described in each embodiment of the present application.

An embodiment of the present application further provides a device for synchronizing the time delay circuit, which is configured to implement the above-mentioned embodiments and preferred implementations, and those described contents will not be repeated. As described below, the term “module” can implement a combination of software and/or hardware with the predetermined functions. Although the device described in the following embodiments is preferably implemented in software, the implementation of hardware, or a combination of software and hardware, is also possible and conceived.

FIG. 4 is a structural block diagram of a device for synchronizing the time delay circuit according to an embodiment of the present application. As shown in FIG. 4, the device applied to a radio frequency chip includes an initialization module 10 and an alignment module 20.

The initialization module 10 is configured to initialize all clock dividers based on the synchronization pulse signal generated by the air interface pulse signal, to synchronize the initial phases of a plurality of system clocks generated by frequency division the high-frequency clock division.

The alignment module 20 is configured to align the read pointer or the write pointer at the first buffer RAM of the radio frequency chip based on the synchronization pulse signal, so as to synchronize a plurality of sending channels.

FIG. 5 is another structural block diagram of the device for synchronizing the time delay circuit according to an embodiment of the present application. As shown in FIG. 5, the device applied to a main control chip includes a synchronization module 30.

The synchronization module 30 is configured to align the read pointer or the write pointer at the second buffer RAM of the main control chip based on the synchronization pulse signal generated by the air interface pulse signal, so as to synchronize a plurality of receiving channels.

It should be noted that the above modules can be implemented by software or hardware. For the latter, it can be implemented in the following ways, but not limited to: the above modules are all located inside the same processor; or the above modules are located inside different processors in any combination.

To facilitate the understanding of the technical solutions of the present application, the following will be described in detail in combination with the embodiments under specific scenarios.

In an embodiment of the present application, a consistency implementation method for a high-precision delay circuit [eos] is proposed based on the synchronization pulse signal. The overall structure is relatively simple and can adapt to synchronization of working scenarios, such as a working scenario with a single chip and a single channel, a working scenario with a single chip and multiple channels, and a working scenario with multiple chips and multiple channels. For the delay calibration circuit with high precision, the initial phase of the system clock is synchronized based on the air interface pulse signal, and then the digital clock domain and the analog high-frequency clock domain are compensated. In this way, the delay calibration accuracy can be improved to the nanosecond level.

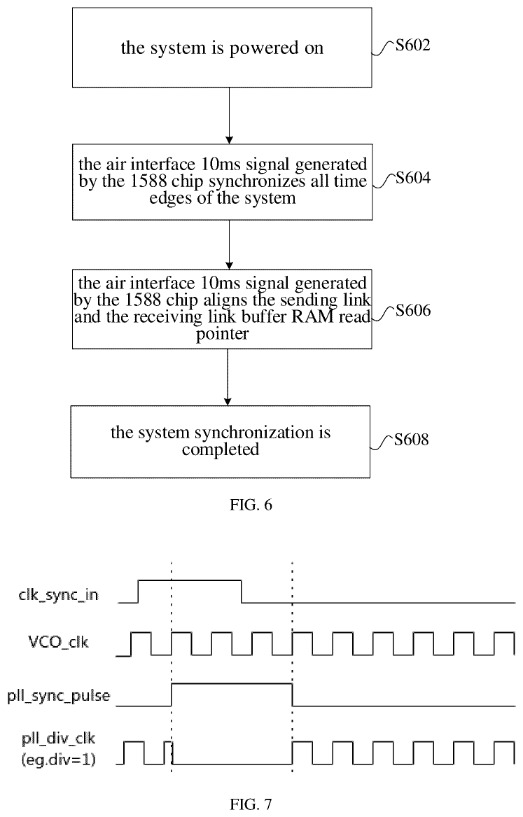

FIG. 6 is a flowchart showing the system synchronization calibration according to an embodiment of the present application. As shown in FIG. 6, the process mainly includes system clock synchronization and buffer RAM read pointer alignment, and specifically includes steps of S602 to S608.

Step S602, the system is powered on.

Step S604, the air interface 10 ms signal generated by the 1588 chip synchronizes all time edges of the system.

Step S606, the air interface 10 ms signal generated by the 158 chip aligns the sending link and the receiving link buffer RAM read pointer.

Step S608, the system synchronization is completed.

In this embodiment, the 1588 chip synchronization clock source is configured, and the high-precision delay synchronization development is turned on after the system is powered on to achieve high-precision delay synchronization without excessive configuration.

FIG. 7 is a schematic diagram showing clock alignment according to an embodiment of the present application. The air interface signal clk_sync_in inputted by the chip PAD is sampled by the system high-frequency clock VCO_clk, to generate the pll_sync_pulse signal. The frequency of the high-frequency clock VCO_clk will reach 16 GHz, and the air interface signal clk_sync_in is an air interface pulse signal generated by the frequency division of the GPS 1PPS signal, which is generally a high level for a period of time of an integer multiple of the period T (T is greater than 0). For example, 10 ms, clk_sync_in and VCO_clk are asynchronous, so that pll_sync_pulse and actual clk_sync_in will lag behind by at most one VCO_clk. pll_sync pulse is generated by the synchronous release of clk_sync_in when the VCO_clk clock domain is asynchronously reset. All clock dividers are initialized by pll_sync_pulse, so that the clock phases generated by the VCO_clk frequency division can be aligned.

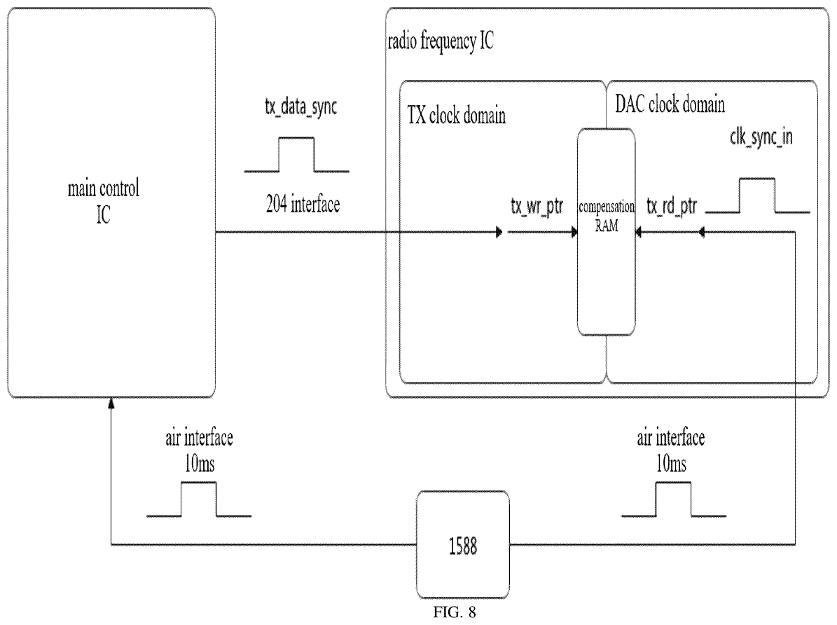

FIG. 8 is a schematic diagram of a high-precision delay sending circuit according to an embodiment of the present application. As shown in FIG. 8, in the TX (sending) data direction, the first pll_sync pulse resets the RAM read pointer tx_rd ptr to the initial position tx_rd_addr_init. According to the RAM read clock frequency, the RAM depth is designed to ensure that the displacement of tx_rd ptr within a 10 ms period is a multiple of the RAM depth. In this way, each time the pll_sync_pulse signal reaches the buffer RAM, tx_rd_ptr will only be located at the position tx_rd_addr_init. If tx_rd_ptr is not located at the position tx_rd_addr_init when the pll sync pulse signal arrives, it means that the system clock is operating with deviation, and tx_rd ptr needs to be reset to the position tx_rd_addr_init. The pll_sync pulse signal continuously checks tx_rd ptr to ensure that the DAC sending clock is strictly synchronized, thereby ensuring that the data sending delay is constant.

clk_sync_in will also be provided to the main control chip (Integrated Circuit Chip, IC) of the system to be converted into a synchronization signal tx_data_sync. tx_data_sync synchronizes the timing of sending data and is attached to the data frame header for transmission. After tx_data_sync is sent to the digital analog converter (DAC) module for the first time, the write address pointer tx_wr_ptr of the reset buffer RAM will be reset to the initial position tx_wr_addr_init. Subsequently, each time tx_data_sync reaches the write side of the buffer RAM, the tx_wr_ptr in this case will be compared with tx_wr_addr_init. If difference exists, tx_wr_ptr will be reset to tx_wr_addr_init.

In this embodiment, in order to reduce the frequent jumps of tx_wr_ptr, an address comparison window tx_wr_addr_threhold is further added. When tx_data_sync reaches the write side of the buffer RAM, if the value of tx_wr_ptr falls within the range of tx_wr_addr_init±tx wr_addr_threhold, tx_wr_ptr may not be reset.

In this embodiment, adjusting the value of tx_wr_addr_init means adjusting the transmission delay of the entire TX link. tx_data_sync follows the data and will cross different clock domains. There is an uncertainty of a clock period when each cross-clock domain transmission occurs.

Through the above embodiments, the synchronization of multiple TX channels on a single chip can be achieved, and the synchronization of a plurality of TX channels on a multi-chip system can also be achieved.

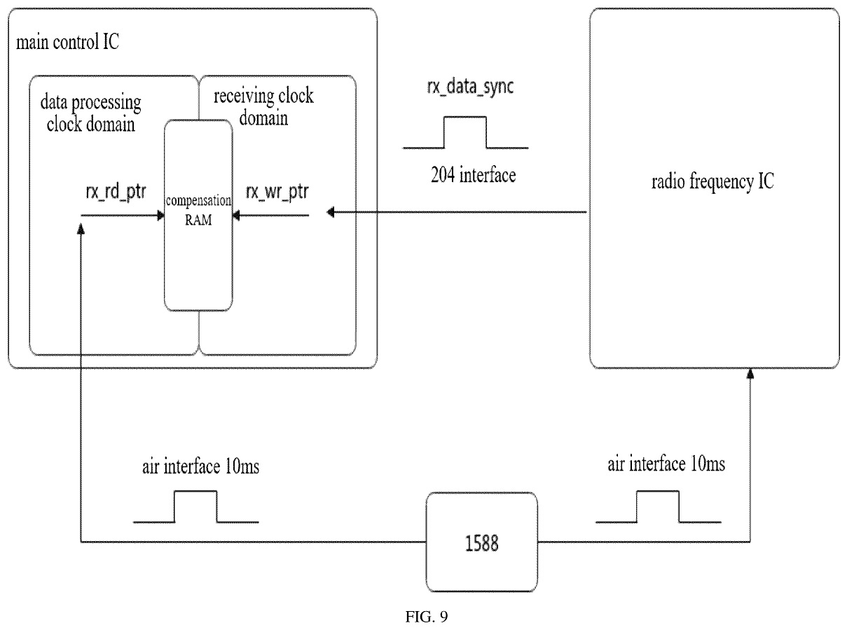

FIG. 9 is a schematic diagram of the high-precision delay receiving circuit according an embodiment of the present application. In the RX (receiving) data direction, clk_sync_in will be provided to the radio frequency IC system to be converted into rx_data_sync, synchronize the data transmission frequency, and will be configured as the data frame header for transmission. rx_data_sync will follow data and cross different clock domains, and there is an uncertainty of a clock period during each cross-clock domain transmission. After rx_data_sync is first sent to the main control IC receiving clock domain, the write address pointer rx_wr_ptr of the buffer RAM will be reset to the initial position rx_wr_addr_init. Subsequently, each time the rx_data_sync buffer reaches the RAM write side, the rx wr_ptr in this case will be compared with rx_wr_addr_init. If difference exists, the pointer rx_wr_ptr will be reset to the position rx_wr_addr_init.

In this embodiment, in order to reduce the frequent jumps of rx_wr_ptr, an address comparison window rx_wr_addr_threhold is further added. When rx_data_sync reaches the buffer RAM write side, if the value of rx_wr_ptr falls within the range of rx_wr_addr_init±rx_wr_addr_threhold, rx_wr_ptr will not be reset. At the same time, adjusting the value of rx wr_addr_init can adjust the transmission delay of the entire RX link.

The clk_sync_in signal is further configured to reset the buffer RAM read pointer (rx_rd_ptr) to the specified position rx_rd_addr_init. According to the RAM read clock frequency, the depth of the RAM is designed to ensure that the displacement of rx_rd ptr within the 10 ms period is a multiple of the RAM depth. Subsequently, each time the clk_sync_in signal reaches the buffer RAM, rx_rd ptr will be located at the position rx_rd_addr_init. If rx_rd_ptr is not located at the position rx_rd_addr_init when the clk_sync_in signal arrives, it means that the system clock has deviated and rx_rd ptr needs to be reset to the position rx_rd_addr_init. The clk_sync_in signal continuously synchronizes rx_rd ptr to achieve strict synchronization of the receiving clock, to ensure that the data reception delay is fixed.

Through the above embodiments, synchronization of multiple RX channels on a single chip can be achieved, and synchronization of a plurality of RX channels in a multi-chip system can also be achieved.

The present application can be applied to the baseband and radio frequency transceiver systems of terminals or base stations, and supports high-precision delay calibration with multi-link, multi-clock domain, and multi-working modes.

In the above embodiments of the present application, the high-precision delay consistency circuit mainly adopts a hardware implementation method, and is configured to align a plurality of clock edges of the system during system initialization based on the air interface pulse signal. In addition, by compensating ram, the data sending, data receiving and using ports are compensated synchronously, thereby achieving high-precision time delay consistency at the nanosecond level. In addition, the high-precision delay consistency circuit ensures time delay consistency both on the sending and using data sides, and can be configured by software to achieve the delay of the entire system, which has flexible configurability.

The present application further provides a computer-readable storage medium, which stores a computer program. The computer program is configured to execute steps of the method according to any one of the above embodiments when operating.

In an exemplary embodiment, the above computer-readable storage medium may include but is not limited to: the U disk, the read-only memory (ROM), the RAM, the mobile hard disk, the disk or the optical disk, and the like, which can store computer programs.

The present application further provides an electronic device including a memory and a processor. A computer program is stored in the memory, and the processor is configured to operate the computer program to execute steps of the method according to any one of the above embodiments.

In an exemplary embodiment, the above electronic device may further include a transmission device and an input/output device. The transmission device is connected to the above processor, and the input/output device is connected to the above processor.

The specific examples in this embodiment can refer to the embodiments described above and the exemplary implementations, which will not be repeated here.

Obviously, those skilled in the art should understand that the above modules or steps of the present application can be implemented by a general computer device, they can be concentrated on a single computer device, or distributed on a network composed of a plurality of computer devices, and they can be implemented by a program code executable by a computer device, so that they can be stored in a storage device and executed by the computer device. In some cases, shown or described steps can be executed in a different order than here, or they can be made into individual integrated circuit modules respectively, or a plurality of modules or steps can be made into a single integrated circuit module for implementation. In this way, the present application is not limited to any specific combination of hardware and software.

The above are only some preferred embodiments of the present application, and do not limit the scope of the present application thereto. For those skilled in the art, he present application may have various modifications and variations. Any modification, equivalent replacement, improvement, and the like, made within the principles of the present application shall fall within the claimed scope of the present application.

1. A method for synchronizing a time delay circuit, comprising:
initializing, by a radio frequency chip, all clock dividers based on a synchronization pulse signal generated by an air interface pulse signal, to synchronize initial phases of a plurality of system clocks generated by frequency division of a high-frequency clock; and
aligning a read pointer or a write pointer at a first buffer random access memory (RAM) of the radio frequency chip to synchronize a plurality of sending channels based on the synchronization pulse signal.

2. The method for synchronizing the time delay circuit according to claim 1, wherein the aligning the read pointer or the write pointer at the first buffer RAM of the radio frequency chip based on the synchronization pulse signal comprises:
resetting the read pointer of the first buffer RAM to a first initial position based on a first synchronization pulse signal; and
resetting the write pointer of the first buffer RAM to a second initial position based on a second synchronization pulse signal.

3. The method for synchronizing the time delay circuit according to claim 2, wherein before the resetting the read pointer of the first buffer RAM to the first initial position based on the first synchronization pulse signal, the method for synchronizing the time delay circuit further comprises:
setting a depth of the first buffer RAM to enable a displacement of the read pointer in one period of the air interface pulse signal to be a multiple of the depth of the first buffer RAM.

4. The method for synchronizing the time delay circuit according to claim 2, wherein before the resetting the write pointer of the first buffer RAM to the second initial position based on the second synchronization pulse signal, the method for synchronizing the time delay circuit further comprises:
generating, by a main control chip, the second synchronization pulse signal based on the air interface pulse signal, and synchronizing a timing of sending the second synchronization pulse signal according to a writing data timing of the write pointer of the first buffer RAM.

5. The method for synchronizing the time delay circuit according to claim 4, wherein the synchronizing the timing of sending the second synchronization pulse signal comprises:
attaching the second synchronization pulse signal to a data frame header and sending it to the first buffer RAM.

6. The method for synchronizing the time delay circuit according to claim 5, wherein the resetting the write pointer of the first buffer RAM to the second initial position based on the second synchronization pulse signal comprises:
after the second synchronization pulse signal reaches a write side of the first buffer RAM, comparing, by the radio frequency chip, a current position of a write address pointer of the first buffer RAM with the second initial position; in response to that the current position of the write address pointer of the first buffer RAM is not the second initial position, resetting, by the radio frequency chip, the write address pointer of the first buffer RAM to the second initial position.

7. The method for synchronizing the time delay circuit according to claim 6, wherein the resetting the write pointer of the first buffer RAM to the second initial position based on the second synchronization pulse signal further comprises:
setting a first address comparison window; after the second synchronization pulse signal reaches the write side of the first buffer RAM, in response to that the current position of the write address pointer of the first buffer RAM falls within a range where the second initial position overlaps the first address comparison window, skipping resetting the current position of the write address pointer of the first buffer RAM.

8. A method for synchronizing a time delay circuit, comprising:
aligning a read pointer or a write pointer at a second buffer random access memory (RAM) of a main control chip based on a synchronization pulse signal generated by an air interface pulse signal, to synchronize a plurality of receiving channels.

9. The method for synchronizing the time delay circuit according to claim 8, wherein the aligning the read pointer or the write pointer at the second buffer RAM of the main control chip based on the synchronization pulse signal comprises:
resetting the read pointer of the second buffer RAM to a third initial position based on a third synchronization pulse signal; and
resetting the write pointer of the second buffer RAM to a fourth initial position based on a fourth synchronization pulse signal.

10. The method for synchronizing the time delay circuit according to claim 9, wherein before the resetting the read pointer of the second buffer RAM to the third initial position based on the third synchronization pulse signal comprises:
setting a depth of the second buffer RAM, to enable a displacement of the read pointer in one period of the air interface pulse signal is a multiple of the depth of the second buffer RAM.

11. The method for synchronizing the time delay circuit according to claim 9, wherein the resetting the write pointer of the second buffer RAM to the fourth initial position based on the fourth synchronization pulse signal comprises:
generating, by a radio frequency chip, the fourth synchronization pulse signal based on the air interface pulse signal, attaching the fourth synchronization pulse signal to a data frame header and sending it to the second buffer RAM.

12. The method for synchronizing the time delay circuit according to claim 11, wherein the resetting the write pointer of the second buffer RAM to the fourth initial position based on the fourth synchronization pulse signal comprises:
in response to that the fourth synchronization pulse signal is sent to a write side of the second buffer RAM for a first time, resetting, by the main control chip, the write pointer of the second buffer RAM to the fourth initial position; and
in response to that the fourth synchronization pulse signal is sent to the write side of the second buffer RAM not for the first time, comparing, by the main control chip, a current position of a write address pointer of the second buffer RAM with the fourth initial position, and resetting the write address pointer of the second buffer RAM to the fourth initial position in response to that the current position of the write address pointer of the second buffer RAM is not the fourth initial position.

13. The method for synchronizing the time delay circuit according to claim 12, further comprising:
setting a second address comparison window, after the fourth synchronization pulse signal reaches the write side of the second buffer RAM, in response to that the current position of the write address pointer of the second buffer RAM falls within a range where the fourth initial position overlaps the second address comparison window, skipping resetting the current position of the write address pointer of the second buffer RAM.

14. A device for synchronizing a time delay circuit, applied to a radio frequency chip, comprising:
an initialization module, configured to initialize all clock dividers based on a synchronization pulse signal generated by an air interface pulse signal, to synchronize initial phases of a plurality of system clocks generated by frequency division of a high-frequency clock; and
an alignment module, configured to align a read pointer or a write pointer at a first buffer random access memory (RAM) of the radio frequency chip based on the synchronization pulse signal, to synchronize a plurality of sending channels.

15. (canceled)

16. A computer-readable storage medium, wherein the computer-readable storage medium stores a computer program, and when the computer program is executed by a processor, steps of the method for synchronizing the time delay circuit according to claim 1 are implemented.

17. An electronic device, comprising a memory, a processor, and a computer program stored in the memory and executable on the processor, wherein when the computer program is executed by the processor, steps of the method for synchronizing the time delay circuit according to claim 1 are implemented.

18. A computer-readable storage medium, wherein the computer-readable storage medium stores a computer program, and when the computer program is executed by a processor, steps of the method for synchronizing the time delay circuit according to claim 8 are implemented.

19. An electronic device, comprising a memory, a processor, and a computer program stored in the memory and executable on the processor, wherein when the computer program is executed by the processor, steps of the method for synchronizing the time delay circuit according to claim 8 are implemented.
